(19) United States
(12) Patent Application Publication
(10) Pub. No.: US 2016/0357044 A1
(43) Pub. Date: Dec. 8, 2016

(54) Array Substrate And Manufacturing Method For The Same, And Totally Reflective Type Liquid Crystal Display

(71) Applicant: BOE Technology Group Co., Ltd., Beijing (CN)

(72) Inventors: Zhijun Lv, Beijing (CN); Tailiang Li, Beijing (CN); Tao Gao, Beijing (CN); Ce Ning, Beijing (CN); Shuang Sun, Beijing (CN)

(73) Assignee: BOE Technology Group Co., Ltd., Beijing (CN)

(21) Appl. No.: 14/891,729

(22) PCT Filed: May 22, 2015
(86) PCT No.: PCT/CN2015/079580

§ 371 Date: Nov. 17, 2015

(30) Foreign Application Priority Data
Dec. 10, 2014 (CN) 201410752941.0

(51) Int. Cl. G02F 1/1368; G02F 1/1343; H01L 29/417; H01L 29/45; H01L 29/423; G02F 1/1335; H01L 29/49

(52) U.S. Cl. CPC G02F 1/1368; G02F 1/133553; G02F 1/13439; H01L 29/4908; H01L 29/458; H01L 29/42384; H01L 29/41733; G02F 2201/123; G02F 2203/02

(57) ABSTRACT

The present disclosure discloses an array substrate, comprising a substrate, a plurality of pixel regions on the substrate, and a thin-film transistor formed in each of the pixel regions, each of the pixel regions comprising a pixel electrode region, wherein, the thin-film transistor comprises a gate layer and a source/drain layer formed laminatedly on the substrate; the array substrate further comprises a flat layer and a reflective metal layer formed in sequence on the substrate and covering at least the pixel electrode region and the thin-film transistor; the reflective metal layer is electrically connected to a drain of the thin-film transistor; and at least one of the gate layer and the source/drain layer is formed of a single metal layer. The present disclosure further provides a method for manufacturing the array substrate and a totally reflective type liquid crystal display comprising the array substrate.

### CROSS-REFERENCE TO RELATED APPLICATION

This application is a Section 371 National Stage Application of International Application No. PCT/CN2015/079580, filed 22 May 2015, entitled “Array Substrate And Manufacturing Method For The Same, And Totally Reflective Type Liquid Crystal Display”, which claims priority to Chinese Application No. 201410752941.0, filed on Dec. 10, 2014, incorporated herein by reference in their entirety.

### BACKGROUND

Technical Field

Embodiments of the present invention generally relate to the field of display technology, and particularly, to an array substrate and a method for manufacturing the same, and a totally reflective type liquid crystal display comprising the array substrate.

Description of the Related Art

Since 1990s, it is attempted to achieve display by means of a method without use of back light, and to seek a novel thin-film transistor (TFT) liquid crystal display (LCD) with thin, weight-light construction and low power consumption. It is called as a reflective type thin-film transistor liquid crystal display (Reflective type TFT-LCD) since such method displays image by means of reflecting environmental light.

Reflective type liquid crystal display not only meets power-saving and energy conservation display demands by utilization and modulation of environmental light, but also maintains advantages and characteristics of conventional liquid crystal display, which has become a major trend in the development of current liquid crystal display. However, polarizer must be used in Twisted Nematic (TN) LCD and Super Twisted Nematic (STN) LCD, so it has a murky grey display ground color, low contrast and poor display quality.

For a common TFT-LCD, introduction of a resin layer, as a flat layer, improves overall power consumption of the device and increases aperture ratio and light transmittance, etc. For a totally reflective mode LCD, flatness of the resin layer plays an important role on reflectivity of the reflective type LCD. The reflectivity of the reflective device will vary greatly, even if it is the same reflective metal with same reflection structure to be deposited on the resin layers with different flatness.

### SUMMARY

According to an aspect of the present disclosure, there is provided an array substrate, comprising a substrate, a plurality of pixel regions on the substrate, and a thin-film transistor formed in each of the pixel regions, each of the pixel regions comprising a pixel electrode region, wherein, the thin-film transistor comprises a gate layer and a source/drain layer formed laminatedly on the substrate; the array substrate further comprises a flat layer and a reflective metal layer formed in sequence on the substrate and covering at least the pixel electrode region and the thin-film transistor; the reflective metal layer is electrically connected to a drain of the thin-film transistor; and at least one of the gate layer and the source/drain layer is formed of a single metal layer.

According to another aspect of the present disclosure, there is provided a totally reflective type liquid crystal display comprising the above mentioned array substrate.

According to yet another aspect of the present disclosure, there is provided a method for manufacturing an array substrate, comprising: providing a substrate comprising a plurality of pixel regions which is to form a plurality of pixels, each of the pixel regions comprising a pixel electrode region which is to form a pixel electrode; forming a thin-film transistor in the pixel region, wherein the thin-film transistor comprises a gate layer and a source/drain layer formed laminatedly on the substrate, and, at least one of the gate layer and the source/drain layer is formed of a single metal layer; and forming a flat layer and a reflective metal layer, which cover at least the pixel electrode region and the thin-film transistor, in sequence on the substrate, wherein the reflective metal layer is configured to be electrically connected to a drain of the thin-film transistor.

### BRIEF DESCRIPTION OF THE DRAWINGS

These features and advantages of the present disclosure will become apparent with reference to the accompanying drawings, and the drawings are exemplary and are not intended to limit the present disclosure, in which:

FIG. 1 is a schematic sectional view of an array substrate for a totally reflective type liquid crystal display according to an embodiment of the present invention; and

FIG. 2 is a flowchart of a method for manufacturing an array substrate according to an embodiment of the present invention.

### DETAILED DESCRIPTION OF THE EMBODIMENTS

A further detailed description of the present disclosure has been provided in conjunction with these specific embodiments, as well as the accompanying drawings, in order to clearly understand these objectives, technical solutions, and advantages of the present disclosure.

In addition, in the following detailed description, for explanations and interpretations, lots of specific details are illustrated in order to provide a full understanding on embodiments of the present invention. However, obviously, one or more embodiment without these specific details may also be implemented. In other cases, known structures and devices are reflected in graphical representations in order to simplify the drawings.

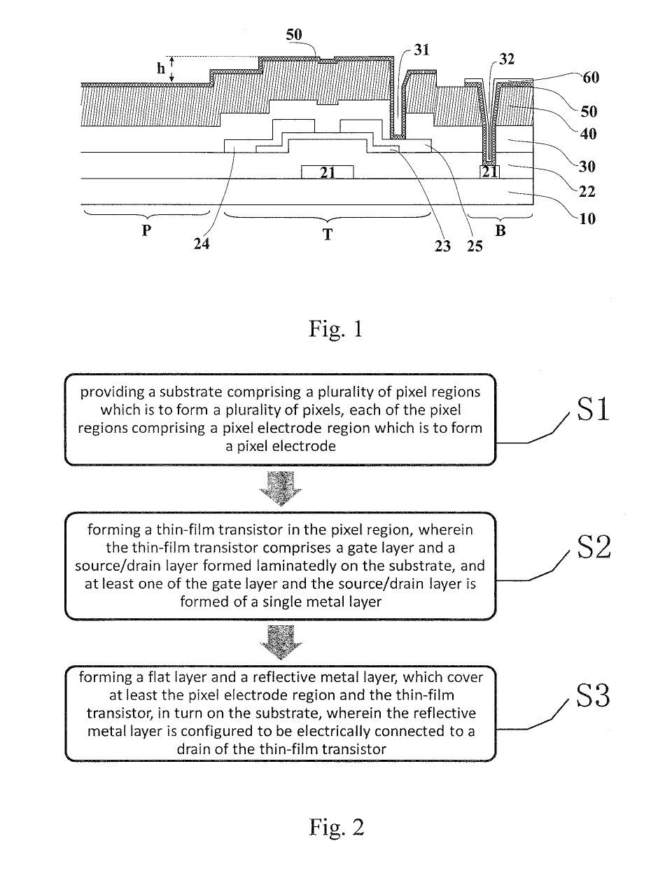

FIG. 1 shows structure of an array substrate according to an exemplary embodiment of the present invention. As shown in FIG. 1, the array substrate mainly comprises a substrate 10; a plurality of pixel regions, defined by data lines and gate lines (no shown) intersecting with each other, on the substrate; and a thin-film transistor T formed in each of the pixel regions, each of the pixel regions comprising a pixel electrode region P. As can be understood, a region B surrounding such array substrate may act as a lead wire bonding region.

The thin-film transistor T comprises a gate layer 21, a gate insulation layer 22, an active layer 23, and a source/drain layer formed laminatedly on the substrate 10 in sequence. The source/drain layer is formed therein with a source 24 and a drain 25 of the thin-film transistor T.

The array substrate further comprises a passivation layer 30, a flat layer 40 and a reflective metal layer 50 formed in sequence on the substrate 10 and covering at least the pixel electrode region P and the thin-film transistor T. In one example, the flat layer 40 may be formed of resin. The reflective metal layer 50 is electrically connected to the drain 25 of the thin-film transistor T, for example, through a via hole 31 formed in the passivation layer 30 and the flat layer 40, and thus, it is also used as a pixel electrode.

The following Table 1 shows measuring data for reflectivity of some metals.

It can be seen from Table 1 that, Al, Ag and AlNd have a relatively high reflectivity, and are capable of achieving an approximate specular reflection, and accordingly, they are preferably used as the reflective metal layer in the TFT array substrate. On the other hand, Ag has an extremely high reflectivity, but it encounters expensive cost and relatively complicated manufacturing process, as a result, it is not suitable for mass production process. AlNd has a slightly lower reflectivity than Ag, but it is low-cost, thereby AlNd may substitute for Ag to implement mass production due to simple manufacturing process. In one example of the present disclosure, AlNd is chosen to form the reflective metal layer.

TABLE 1

| The | | | | | | | | | | | Average | | |
|---|---|---|---|---|---|---|---|---|---|---|---|---|---|
| Metal | | | | | | | | | | | Reflectivity | Homo- | |
| Layer | Thickness | 1 | 2 | 3 | 4 | 5 | 6 | 7 | 8 | 9 | (%) | geneity | 3σ |
| Ti | 2000 Å | 54.55 | 48.33 | 50.47 | 44.71 | 41.45 | 42.9 | 42.65 | 41.57 | 42.39 | 45.45 | 13.6% | 13.89 |
| | | 54.19 | 49.24 | 53.84 | 48.77 | 41.99 | 42.73 | 42.64 | 42.18 | 50.56 | 47.35 | 12.7% | 15.14 |
| Ti/ITO | 2000 Å/ | 39.95 | 38.03 | 42.32 | 37.9 | 32.87 | 33.56 | 33.85 | 33.93 | 39.17 | 36.84 | 12.6% | 10.15 |
| | 120 Å | 42.31 | 37.97 | 41.29 | 35.31 | 31.7 | 32.87 | 34.49 | 33.1 | 39.38 | 36.49 | 14.3% | 11.64 |
| Al | 3000 Å | 97.47 | 97.44 | 97.46 | 97.49 | 97.49 | 97.54 | 97.45 | 97.41 | 97.48 | 97.47 | 0.1% | 0.11 |
| | | 97.53 | 97.51 | 97.48 | 97.51 | 97.46 | 97.49 | 97.49 | 97.46 | 97.59 | 97.50 | 0.1% | 0.12 |
| Ag | 1000 Å | 98.71 | 98.97 | 98.70 | 98.75 | 98.90 | 98.88 | 98.25 | 98.5 | 98.58 | 98.69 | 0.4% | 0.67 |
| | | 99.89 | 99.71 | 99.43 | 100 | 99.72 | 99.5 | 99.6 | 99.48 | 99.5 | 99.65 | 0.3% | 0.59 |
| AlNd | 3000 Å | 96.11 | 96.27 | 96.16 | 96.1 | 96.05 | 96.14 | 96.25 | 96.17 | 94.35 | 95.96 | 1.0% | 1.82 |
| | | 96.32 | 96.37 | 96.36 | 96.26 | 96.25 | 96.28 | 96.34 | 96.29 | 96.34 | 96.31 | 0.1% | 0.13 |

As shown in FIG. 1, in the region of the pixel region where the thin-film transistor T is formed, due to formation and lamination of these layers of the thin-film transistor T, an altitude difference or difference in height h exists between the thin-film transistor T formation region and the pixel electrode region P, in the finally formed array substrate. As described above, for the totally reflective mode LCD, flatness of the flat layer plays an important role on reflectivity of the reflective type LCD. Most of the flat layers, e.g., resin layer, however, follow the shape of the bottom layer to spread out and are sensitive to fluctuation of the bottom layer. A flat layer with a great thickness (usually greater than 1 um) may reduce the altitude difference to some extent, however, in the reflective mode, the reflective metal greatly relies on the whole flatness. The reflectivity of the reflective device will vary greatly, even if it is the same reflective metal with same reflection structure to be deposited on the resin layers with different flatness.

Conventionally, the gate layer and the source/drain layer of the thin-film transistor both adopt a multilayer or composite-layer metal structure having a relatively great thickness, while none of the gate layer and the source/drain layer are formed within the pixel electrode region, as a result, there exists a large altitude difference or difference in height h between the thin-film transistor formation region and the pixel electrode region, the deposited reflective metal layer has a poor whole flatness, especially within the pixel region, thereby resulting in a lower reflectivity of the finally patterned reflective metal layer.

The inventors have found that, by reducing the altitude, especially the above mentioned altitude difference or difference in height h within the pixel region, the flat layer may have a relatively well whole flatness, so that the reflective metal layer formed (e.g., deposited) on the flat layer has an improved reflectivity, and reflects the environmental light in a manner of more approximate specular reflection.

In the present disclosure, at least one or all of the gate layer and the source/drain layer of the thin-film transistor T are formed of a single metal layer, which reduces the altitude difference or difference in height h between the thin-film transistor and the pixel electrode region, and improves the whole flatness of the finally formed reflective metal layer within the pixel region, thus, it improves reflectivity of the reflective metal layer.

The following Table 2 shows reflectivity of the AlNd layer measured under different conditions, in which Columns A, B and C denote reflectivity of the patterned reflective metal layer made of AlNd when the thin-film transistors constructed of electrode structures made of different materials are formed within the pixel region, and Column D denotes reflectivity of the AlNd layer which is directly formed on a completely flat surface.

TABLE 2

| | A: Mo | | C: Mo | |
|---|---|---|---|---|
| | 2200 Å | B: Mo/AlNd/Mo | 2200 Å | D: AlNd |
| Test Number | (240° C.) | 200/3000/1000 Å | (180° C.) | Layer |
| 1 | 80.897 | 63.112 | 80.856 | 100.000 |
| 2 | 81.107 | 64.426 | 80.871 | 96.912 |
| 3 | 80.840 | 93.290 | 80.986 | 96.525 |
| 4 | 81.432 | 64.558 | 87.751 | 96.521 |
| 5 | 81.030 | 65.726 | 81.889 | 96.477 |
| 6 | 81.099 | 65.341 | 81.154 | 96.468 |
| 7 | 80.935 | 64.380 | 81.024 | 96.478 |
| 8 | 81.496 | 65.293 | 81.081 | 96.522 |
| 9 | 82.051 | 64.403 | 80.683 | 96.481 |
| Average | 81.210 | 64.503 | 81.144 | 96.485 |
| Reflectivity | | | | |
| of AlNd Layer | | | | |

In one example of the present disclosure, as shown in Table 2, the gate layer and the source/drain layer of the thin-film transistor T are both formed of, e.g., molybdenum (Mo) layer with a thickness of 2200 angstrom (Å). Compared to the conventional thin-film transistor comprising the gate layer and the source/drain layer formed of Mo/AlNd/Mo composite structure with a thickness of 200/3000/1000 Å (that is, a Mo layer, an AlNd layer and A Mo layer with thickness of 1000 Å, 3000 Å and 200 Å respectively are laminated from bottom to top in sequence), it has a reduced thickness of, only (200+3000+1000) Å−2200 Å=0.2 um. Obviously, this reduction of the thickness reduces the above mentioned altitude difference or difference in height within the pixel region, which causes an average reflectivity of the AlNd layer, used as the reflective metal layer, to be increased at approximately 26%(=(81.210−64.503)/64.503).

In addition, if the gate layer and the source/drain layer of the thin-film transistor T of the present disclosure are both formed of, e.g., molybdenum (Mo) with a thickness of 2200 angstrom (Å), the average reflectivity (81.210% or 81.144%) of the AlNd layer, used as the reflective metal layer, gets closer to the average reflectivity (96.485%) of the AlNd layer which is directly formed on a completely flat surface, than the average reflectivity (64.503%) of the conventional composite electrode structure, accordingly, it reflects the environmental light in a manner of more approximately specular reflection.

In addition, it can be seen from Table 2 that, in the same reflective mode, reflectivity of the same reflective metal can vary with some factors such as deposition conditions. Reflectivity of the same metal that has been deposited and patterned under different temperatures (Column A: 240° C., Column C: 180° C.) changes little, for example, single layer of Mo electrode in Column A and Column C. The metal that has been deposited but not patterned has the highest reflectivity. In the array substrate, the portion of the reflective metal layer forming in the surrounding region B enables a pure specular reflection of high reflectivity since the surrounding region B is not patterned and still remains in a flat structure; in contrast, the pixel region is formed with a patterned structure and thus there is an altitude difference or difference in height, accordingly, the specular reflection is incomplete and the reflectivity reduces. Compared to the conventional thin-film transistor comprising the gate layer and the source/drain layer of composite electrode structure, in the present disclosure, at least one or all of the gate layer and the source/drain layer of the thin-film transistor are formed of a single metal layer, which reduces the above mentioned altitude difference or difference in height within the pixel region, thus, it obviously increases reflectivity of the reflective metal layer.

It can be understood that, a Mo layer having a thickness of 2200 Å is taken as an example for comparison in these examples of Table 2, however, other metal layers having different thickness may be adopted, depending on factors including electrical conductivity, etching rate of metal, etc.

During the manufacturing of the array substrate, the etchings applied on the passivation layer and/or the gate insulation layer having the thickness of about 5000 Å-7000 Å are inevitably applied on the gate layer or the source/drain layer underneath. It has been proved in practice that, in order to ensure that the non-metal layer (the passivation layer and/or the gate insulation layer) is etched completely without any residue, over-etching time by 15%-30% is needed generally. The inventors have found that, in conventional reflective type liquid crystal display, due to presence of this over-etching as well as differences in factors such as etching rate for metal and non-uniform metal deposition, etc., for Mo/AlNd/Mo and other “composite” electrode structures, metal Mo in the top layer may be partially over-etched, further, metal AlNd in the middle will not be protected well from being corroded in case that developer solution reacts strongly with the AlNd. However, in the present disclosure, at least one or all of the gate layer and the source/drain layer of the thin-film transistor is formed of a single metal layer, as a result, it avoids signal transmission from interruption, which is caused by corrosion of AlNd due to over-etching.

The gate layer and the source/drain layer of the thin-film transistor may be formed of any suitable metal. In one example of the present disclosure, the gate layer 21 and the source/drain layer 24, 25 of the thin-film transistor T may be formed of the same metal, e.g., one of molybdenum, copper and aluminum. In another example, the gate layer and the source/drain layer may have the same thickness.

Since no patterned structure is formed within the pixel electrode region, portions of the passivation layer and the flat layer within the pixel electrode region are substantially flat. However, in the embodiments of the present invention, a portion of the reflective metal layer covering the pixel electrode region is substantially flat. Moreover, the increased reflectivity results in that the environmental light may be reflected in a manner of approximate specular reflection, which increases light use efficiency, brightness and contrast ratio of the liquid crystal display.

As shown in FIG. 1, in one example, the reflective metal layer 50 may further be formed within the surrounding lead wire region B. The portion of the reflective metal layer 50 forming in the surrounding lead wire region B and the portion of the reflective metal layer 50 forming in the pixel region (P+T regions) are separated from each other, and electrically connected to the gate layer 21 through a via hole 32 in the passivation layer 30 and the gate insulation layer 22. The portion of the reflective metal layer 50 forming in the surrounding lead wire region may further be covered with a tin indium oxide (ITO) layer 60, as a result, the gate layer 21 is leaded out by means of the reflective metal layer 50 and the ITO layer 60. Of course, the source and drain of the thin-film transistor may be leaded out by means of the portion of the reflective metal layer forming in the surrounding lead wire region, although not shown.

The array substrate according to the present disclosure may be used in a totally reflective type liquid crystal display, to improve light use efficiency, brightness and contrast ratio of the liquid crystal display.

A method for manufacturing the above mentioned array substrate according to the present disclosure will be described hereafter. FIG. 2 shows a flowchart of a method for manufacturing an array substrate according to an embodiment of the present invention. First of all, in step S1, a substrate, e.g., glass substrate, is provided. As shown in FIG. 1, the substrate comprises a plurality of regions including a plurality of pixel regions P which is generally located in the middle and is to form a plurality of pixels, and a surrounding lead wire bonding region. Each of the pixel regions comprises a pixel electrode region which is to form a pixel electrode and a region which is to form a thin-film transistor.

In step S2, a thin-film transistor is formed in each pixel region, by laminating and patterning a gate layer 21, a gate insulation layer 22, an active layer 23, and a source/drain layer on the substrate in sequence. The source/drain layer is formed therein with a source 24 and a drain 25 of the thin-film transistor T. According to an embodiment of the present invention, at least one of the gate layer and the source/drain layer is formed of a single metal layer, which reduces the altitude difference or difference in height between a region where the thin-film transistor is located and the pixel electrode region. In one example, the gate layer and the source/drain layer may both be formed of a single metal layer, e.g., selected from one of molybdenum, copper and aluminum. The gate layer and the source/drain layer may be formed of one and the same metal, which simplifies manufacturing process. For example, they may have the same thickness, e.g., both are formed of molybdenum layer with a thickness of 2200 Å.

In step S3, a flat layer 40 and a reflective metal layer 50, which cover at least the pixel electrode region P and the thin-film transistor T, are formed on the substrate in sequence, wherein the reflective metal layer 50 is electrically connected to a drain of the thin-film transistor. In one example, prior to formation of the flat layer, a passivation layer 30, which covers at least the pixel electrode region P and the thin-film transistor T, is formed on the substrate 10. In one example, the reflective metal layer 50 is electrically connected to a drain 25 of the thin-film transistor T, e.g., through a via hole 31 formed in the passivation layer 30 and the flat layer 40, and thus, it is also used as a pixel electrode. In one example, the flat layer 40 may be formed of resin. In one example, as shown in FIG. 1, the portion of the reflective metal layer 50 covering the pixel electrode region P may be substantially flat, and this portion may be formed of one of Al, Ag and AlNd. In the present disclosure, process for forming each layer may not be limited, e.g., it comprises semiconductor processes such as deposition, sputtering, etc.

Although these embodiments of the present invention have been shown and described, it would be appreciated by those skilled in the art that changes may be made in these embodiments without departing from the principles and spirit of the present disclosure, the scope of which is defined in the claims and their equivalents.

Obviously, those skilled in the art may make various changes and modifications within principles and spirit of the present disclosure. Accordingly, the present disclosure intends to contain these changes and modifications if they are within the scope of the present disclosure defined in the claims and their equivalents.

1. An array substrate, comprising a substrate, a plurality of pixel regions on the substrate, and a thin-film transistor formed in each of the pixel regions, each of the pixel regions comprising a pixel electrode region, wherein,
the thin-film transistor comprises a gate layer and a source/drain layer formed laminatedly on the substrate;
the array substrate further comprises a flat layer and a reflective metal layer formed in sequence on the substrate and covering at least the pixel electrode region and the thin-film transistor;
the reflective metal layer is electrically connected to a drain of the thin-film transistor; and
at least one of the gate layer and the source/drain layer is formed of a single metal layer.

2. The array substrate of claim 1, wherein the gate layer and the source/drain layer both are formed of a single metal layer.

3. The array substrate of claim 2, wherein the gate layer and the source/drain layer are formed of one and the same metal.

4. The array substrate of claim 3, wherein the gate layer and the source/drain layer have the same thickness.

5. The array substrate of claim 3, wherein the metal comprises one of molybdenum, copper and aluminum.

6. The array substrate of claim 4, wherein the gate layer and the source/drain layer both are formed of a molybdenum layer with a thickness of 2200 Å.

7. The array substrate of claim 1, wherein a portion of the reflective metal layer covering the pixel electrode region is substantially flat, and the reflective metal layer is formed of one of Al, Ag and AlNd.

8. (canceled)

9. The array substrate of claim 1, wherein the flat layer comprises a resin layer.

10. The array substrate of claim 1, further comprising a surrounding lead wire region, wherein
the reflective metal layer is further formed on the surrounding lead wire region; and
a portion of the reflective metal layer located on the surrounding lead wire region is covered with an indium tin oxide layer.

11. A totally reflective type liquid crystal display, comprising an array substrate of claim 1.

12. A method for manufacturing an array substrate, comprising:
providing a substrate comprising a plurality of pixel regions which is to form a plurality of pixels, each of the pixel regions comprising a pixel electrode region which is to form a pixel electrode;
forming a thin-film transistor in the pixel region, wherein the thin-film transistor comprises a gate layer and a source/drain layer formed laminatedly on the substrate, and at least one of the gate layer and the source/drain layer is formed of a single metal layer; and
forming a flat layer and a reflective metal layer, which cover at least the pixel electrode region and the thin-film transistor, in sequence on the substrate, wherein the reflective metal layer is configured to be electrically connected to a drain of the thin-film transistor.

13. The method of claim 12, wherein the gate layer and the source/drain layer both are formed of a single metal layer.

14. The method of claim 13, wherein the gate layer and the source/drain layer are formed of one and the same metal.

15. The method of claim 14, wherein the gate layer and the source/drain layer have the same thickness.

16. The method of claim 14, wherein the metal comprises one of molybdenum, copper and aluminum.

17. The method of claim 15, wherein the gate layer and the source/drain layer both are formed of a molybdenum layer with a thickness of 2200 Å.

18. The method of claim 12, wherein a portion of the reflective metal layer covering the pixel electrode region is substantially flat, and the reflective metal layer is formed of one of Al, Ag and AlNd.

19. The method of claim 18, wherein the reflective metal layer is formed of one of Al, Ag and AlNd.

20. The method of claim 12, wherein the flat layer comprises a resin layer.

21. The method of claim 12, wherein the substrate further comprises a surrounding lead wire region, wherein the reflective metal layer is further formed on the surrounding lead wire region; the method further comprises:
forming an indium tin oxide layer, which covers a portion of the reflective metal layer located on the surrounding lead wire region, on the substrate.

22. A totally reflective type liquid crystal display, comprising an array substrate of claim 9.
